(19) United States
(12) Patent Application Publication
(10) Pub. No.: US 2010/0090239 A1
(43) Pub. Date: Apr. 15, 2010

(54) CERAMIC PACKAGE STRUCTURE OF HIGH POWER LIGHT EMITTING DIODE AND MANUFACTURING METHOD THEREOF

(75) Inventors: SHEN BO LIN, HSINCHU COUNTY (TW); PIN CHUAN CHEN, HSINCHU COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: ADVANCED OPTOELECTRONIC TECHNOLOGY INC., HSINCHU COUNTY (TW)

(21) Appl. No.: 12/573,430

(22) Filed: Oct. 5, 2009

(30) Foreign Application Priority Data
Oct. 13, 2008 (TW) 097139144

(51) Int. Cl. H01L 33/00; H01L 21/50

(52) U.S. Cl. 257/98; 438/27; 257/99; 257/E33.058; 257/E21.499

(57) ABSTRACT

A ceramic package structure of a high power light emitting diode comprises a light emitting diode die, a ceramic substrate, at least two conductive rods, and an electrical conductive film. The ceramic substrate comprises a first surface and a second surface opposite the first surface. A reflecting cup is disposed on the first surface. At least two through holes are disposed on the bottom of the reflecting cup. The electrical conductive film comprises a first electrode and a second electrode, and is fixed to the second surface. The at least two conductive rods are respectively filled in the at least two through holes, and are respectively connected to the first electrode and the second electrode. The LED diode is mounted on one or at least two of the conductive rods, and is electrically connected to the at least two conductive rods.

### BACKGROUND OF THE INVENTION

1. Field of the Invention

The present invention relates to a ceramic package structure of a high power light emitting diode and a manufacturing method thereof, and relates more particularly to a ceramic substrate for the package of a high power light emitting diode.

2. Description of the Related Art

LEDs are generally applied to the indication lamps of household appliances, lighting apparatuses, the back light modules of liquid crystal displays, third brake lights for vehicles, etc. because of their compact size, high illuminating efficiency and longevity. In recent years, several LED materials such as AlGzInP and AlGaInN have been successfully developed, and the LEDs can replace traditional incandescent lamps in various applications.

FIG. 1 shows an exploded diagram of the package structure of a high power LED according to Taiwanese patent No. 1271835. As shown in FIG. 1, the LED package structure comprises a base 100, adhesive 160, a reflecting plate 110, an LED 150, a plurality of leads 120 and transparent filler 130. The main feature of this package structure is the base 100 which integrates metal and an insulating material 106 into one body. The metal acts as a thermal dissipation seat 102 extending outward from the upper surface, lower surface or lateral surface of the base 100 and a plurality of electrodes 104, located at proper positions around the thermal dissipation seat 102, also extending outward from the upper surface, lower surface or lateral surface of the base 100. The insulating material 106 is disposed between the thermal dissipation seat 102 and the electrodes 104 so that the thermal dissipation seat 102 and the electrodes 104 are combined with each other in an insulating manner. An LED die 105 is mounted on the upper surface of the thermal dissipation seat 102. The positive electrodes and negative electrodes of the LED die 105 are respectively connected to the electrodes 104 on the upper surface of the base 100. An external power source provides the die 105 with current through the electrode 104 on the lower surface of the base 100, the electrode 104 on the upper surface of the base 100, and the leads 120. The reflecting plate 110 is attached to the base 100 by the adhesive 160.

The aforesaid conventional package structure can separate the electrical path from the thermal dissipation path to improve the thermal dissipation ability. However, such a package structure is complicated, and many parts are combined with each other by adhesive. The sealing effect is poor, so water or moisture easily penetrates into the structure so as to further affect the reliability of the LED. Furthermore, the different materials are likely to separate from each other or warp because of their different coefficients of thermal expansion. Therefore, the stability of the strength of the structure is low. Similar problems also exist in another Taiwanese patent, No. I265,647.

Several patent publications such as WO2005/043627, US20040079957 and US20070200127 also disclose the package structure of an LED die. The package structure comprises a substrate, a reflecting plate and a lens. The substrate is made of a thermally conductive and electrically insulating material or a thermally and electrically conductive material. Generally, the substrate comprises an electrically conductive material and a thermally conductive and electrically insulating material formed on the electrically conductive material. The substrate further comprises a lead connecting a mounting pad to an LED die. The reflecting plate is coupled to the substrate and surrounds the mounting pad. The lens substantially covers the mounting pad. The heat generated from the LED die during an operation period can be dissipated through both the substrate (acting as a thermally dissipative sheet at the bottom) and the reflecting plate (acting as a thermally dissipative sheet at the top). The reflecting plate comprises a reflecting surface for directing light from the LED die toward to a desired direction. However, such a package structure still has the aforesaid disadvantage. Therefore, the problems of the complicated structure and process integration should be resolved.

### SUMMARY OF THE INVENTION

The present invention provides a ceramic package structure of a high power light emitting diode and a manufacturing method thereof. The heat generated from an LED die can be dissipated through a ceramic substrate with high thermal dissipation formed by a thermal compressing method.

In order to resolve the aforesaid problems, the present invention provides a ceramic package structure of a high power light emitting diode comprising a light emitting diode die, a ceramic substrate, at least two conductive rods, and an electrically conductive film. The ceramic substrate comprises a first surface and a second surface opposite the first surface. A reflecting cup is disposed on the first surface. At least two through holes are disposed on the bottom of the reflecting cup. The electrically conductive film comprises a first electrode and a second electrode, and is fixed to the second surface. The at least two conductive rods are respectively disposed in the at least two through holes, and are respectively connected to the first electrode and the second electrode. The LED diode is mounted on one or two of the conductive rods, and is electrically connected to the at least two conductive rods.

The present invention further provides a method for manufacturing a ceramic package structure of a high power light emitting diode comprising the steps of: compressing an electrical conductive film to attach to a surface of a ceramic substrate, wherein another surface of the ceramic substrate opposite the electrical conductive film comprises a reflecting cup with at least one concave; patterning the electrical conductive film to form at least one first electrode and at least one second electrode; forming at least two through holes on the bottom of the reflecting cup; respectively disposing at least two conductive rods in the at least two through holes, wherein the at least two conductive rods are respectively connected to the first electrode and the second electrode; mounting an LED die on one or two of the conductive rods; and electrically connecting the LED die to the at least two conductive rods.

### BRIEF DESCRIPTION OF THE DRAWINGS

The invention will be described according to the appended drawings in which:

FIG. 1 shows an exploded diagram of the package structure of a high power LED according to Taiwanese patent No. I265,647;

FIGS. 2A-2J are schematic diagrams illustrating the manufacturing steps of the ceramic package structure of a high power light emitting diode in accordance with the present invention;

FIG. 3 is a top view of the ceramic package structure of a high power light emitting diode in accordance with the present invention;

FIGS. 4A-4I are schematic diagrams illustrating the manufacturing steps of the ceramic package structure of a high power light emitting diode in accordance with another embodiment of the present invention;

FIG. 5 is a top view of the ceramic package structure of a high power light emitting diode in accordance with another embodiment of the present invention; and

FIG. 6 is a top view of the ceramic package structure of a high power light emitting diode in accordance with another embodiment of the present invention.

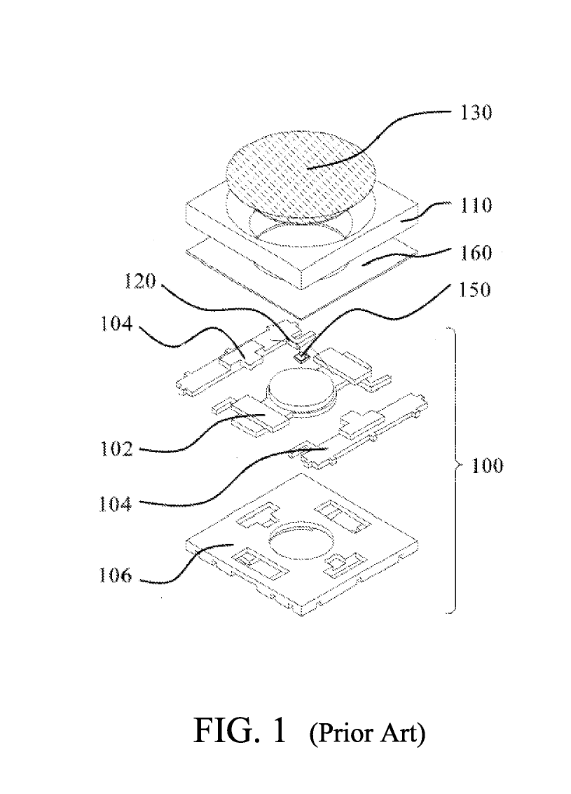

### DETAILED DESCRIPTION OF THE INVENTION

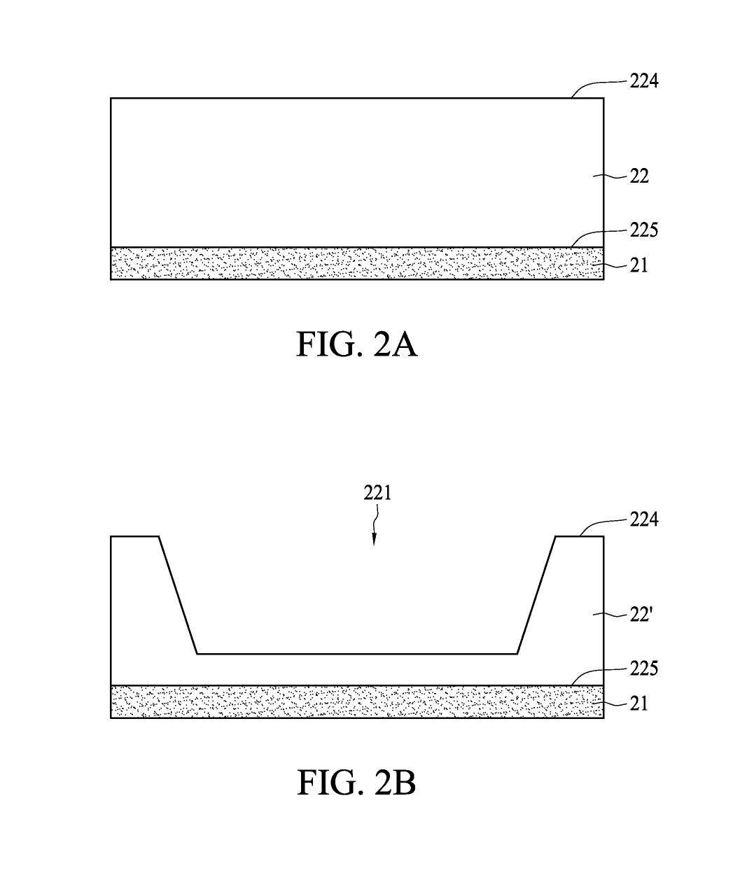

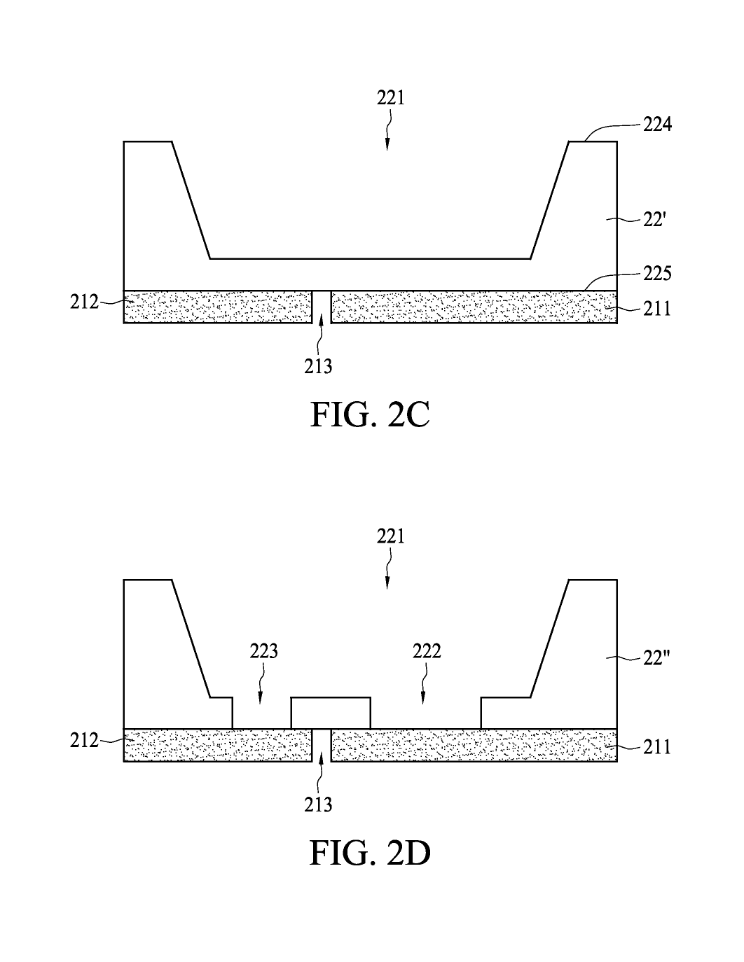

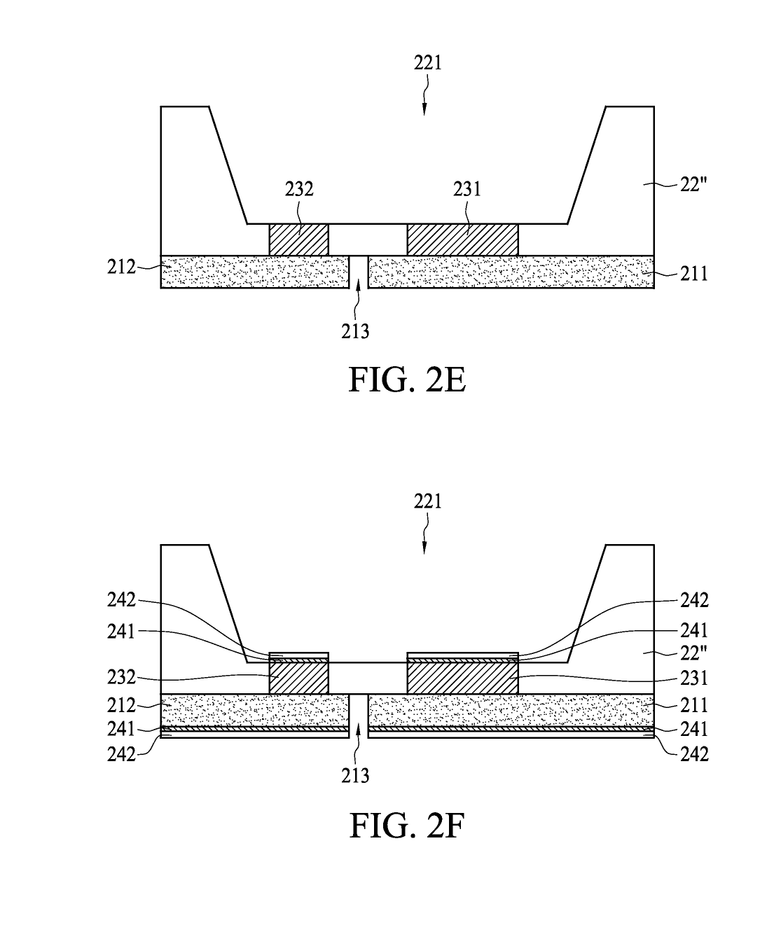

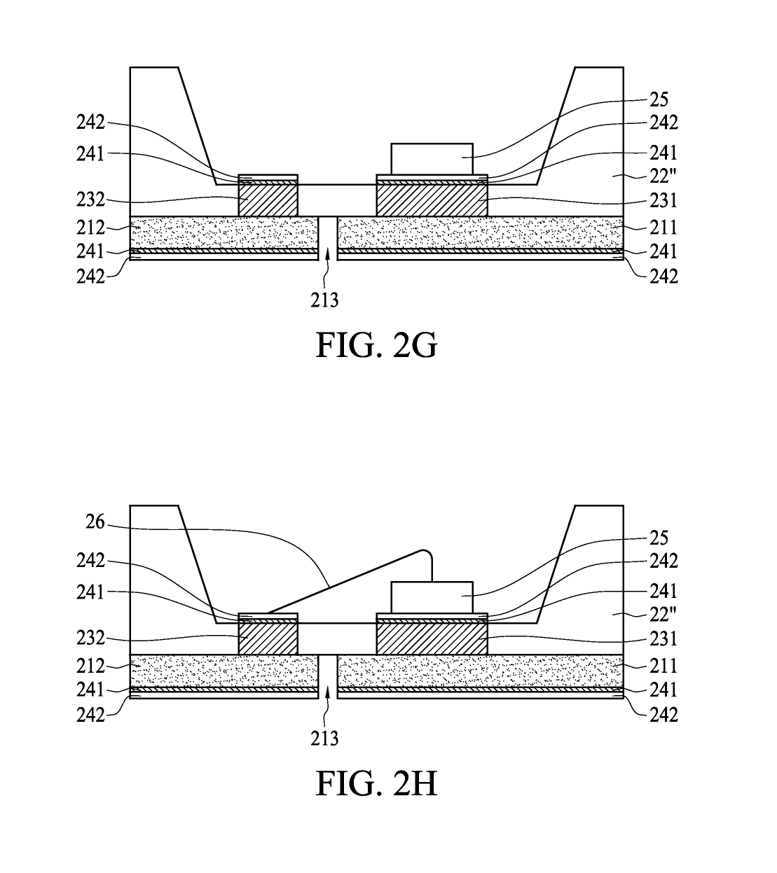

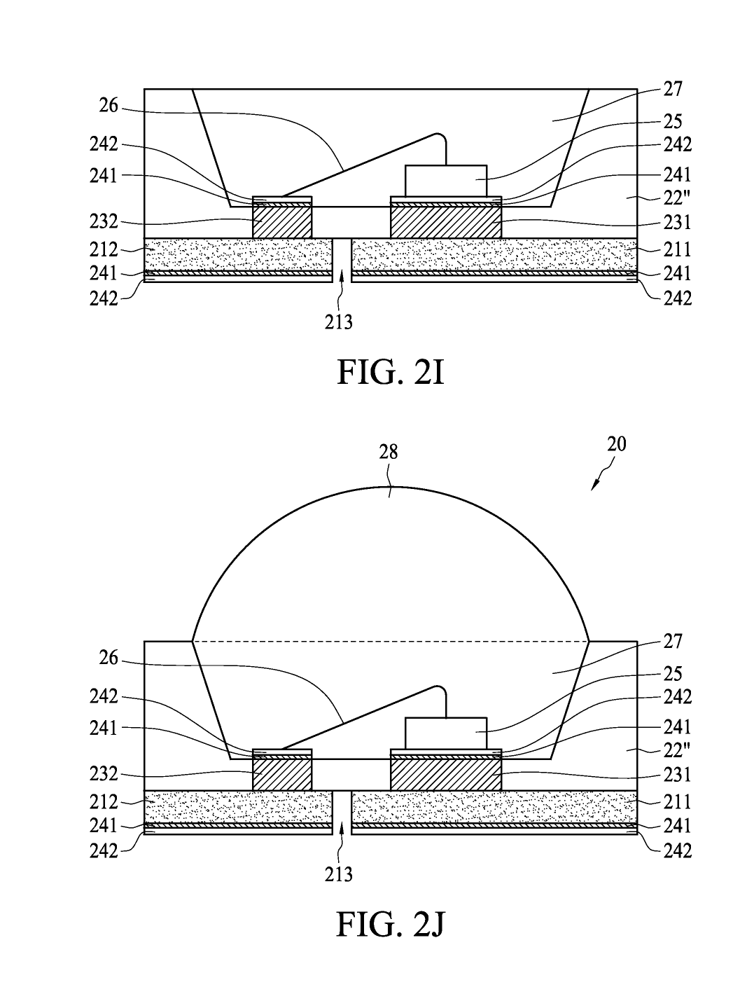

FIGS. 2A-2J are schematic diagrams illustrating the manufacturing steps of the ceramic package structure of a high power light emitting diode in accordance with the present invention. As shown in FIG. 2A, an electrical conductive film 21 is fixed to a second surface 225 of a ceramic substrate 22 by a thermal compression method, wherein the ceramic substrate 22 is an LTCC (Low-Temperature Cofired Ceramics) sheet or an HTCC (High-Temperature Cofired Ceramics) sheet and the electrical conductive film 21 is a copper film.

Referring to FIG. 2B, a reflecting cup 221 is formed on the first surface 224 of the ceramic substrate 22′ using a mechanical drilling method or a laser drilling method. The reflecting cup 221 can direct all of the light from the LED die toward a certain direction (for example, an upward direction is shown in this figure) for emission. Alternatively, the concave reflecting cup 221 is formed on the first surface 224 during the solidification period of the ceramic substrate 22′. No sequential steps such as drilling are needed to form the reflecting cup 221. Thereafter, photolithography, photoresist development and metal etching processes are performed to form a groove 213 on the electrical conductive film 21 for obtaining a default electrode pattern, as shown in FIG. 2C. Accordingly, the first electrode 211 and the second electrode 212 are formed on the second surface 225 of the ceramic substrate 22′.

Similarly, a plurality of through holes 222 and 223 are formed on the bottom of the reflecting cup 221 of the ceramic substrate 22″ using a mechanical drilling method or a laser drilling method, as shown in FIG. 2D. Thereafter, an electrical conductive material such as silver paste, SEM-gold/silver paste, adhesive with silver powders or metal deposited by electroforming is filled in the through holes 222 and 223 to form conductive rods 231 and 232 as a charging circuit and to increase the support stiffness of the structure, as shown in FIG. 2E.

In order to improve the solderability of the first electrode 211 and the second electrode 212, nickel, gold, palladium, or silver as an assistant metal layer is sequentially deposited on the first electrode 211 and the second electrode 212 by electrolysis plating or chemical plating. As shown in FIG. 2F, a nickel layer 241 and a gold layer 242 are not only sequentially deposited on the first electrode 211 and the second electrode 212, but also are plated on the exposed surfaces of the electrical conductive rods 231 and 232 useful for the connections of sequential package processes.

An LED die 25 is attached on the conductive rod 231 further using die bonding or eutectic bonding, as shown in FIG. 2G. The nickel layer 241 and the gold layer 242 on the conductive rods 231 and 232 have a good connection with the LED die 25, and can be soldered with metal wire 26, as shown in FIG. 2H. Through the metal wire 26, the bonding pad on the LED die 25 is connected to the conductive rod 232. The combination of the ceramic substrate 22″ and conductive rods 231 and 232 acts as an electrically conductive lead frame or a chip carrier.

As shown in FIG. 2I, in order to protect the LED die 25 and metal wire 26 from the effects of environmental factors and external force, transparent adhesive 27 such as epoxy and silicone gel can be filled into the reflecting cup 221. The transparent adhesive 27 is filled into the reflecting cup 221 using transfer molding or injection molding to cover the entire LED die 25 for waterproofing and protection. Scattering dots such as titania (TiO₂) or silica (SiO₂) can be added to the transparent adhesive 27.

In order to improve the focusing effect of the LED ceramic package structure 20, a convex lens 28 can be mounted to the upper surface of the transparent adhesive 27, as shown in FIG. 2J. The convex lens 28 is formed by injection molding in advance, and is attached to the upper surface of the transparent adhesive 27. Alternatively, the transparent adhesive 27 and the convex lens 28 are integrated into one part by a single step of transfer molding or injection molding, so the manufacturing steps are reduced and the interface capable of reflecting light is eliminated.

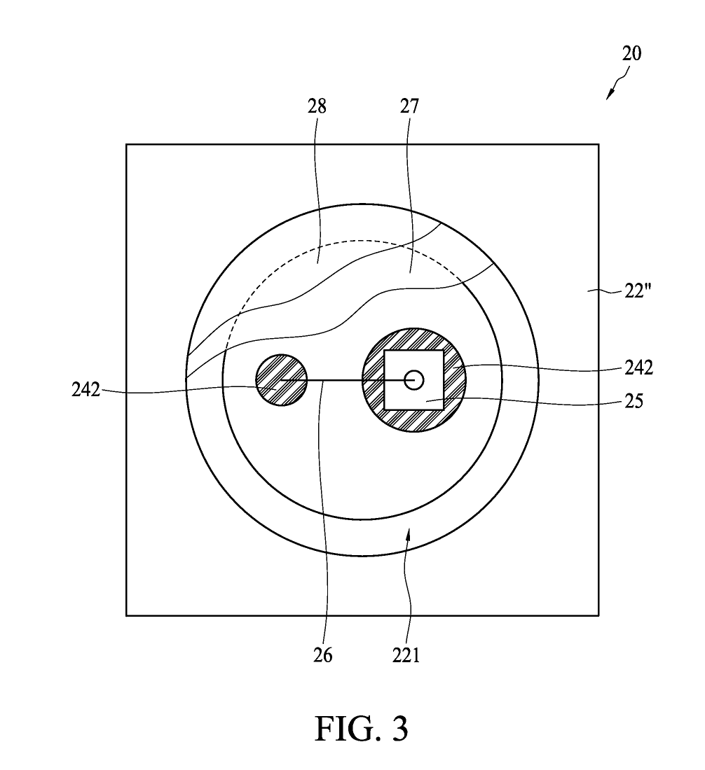

FIG. 3 is a top view of the ceramic package structure of a high power light emitting diode in accordance with the present invention. Two areas of a gold layer 242 are overlaid on the bottom of the reflecting cup 221 of the ceramic substrate 22″. The two areas are on the conductive rods 231 and 232, and the LED die 25 is mounted on the larger area of the gold layer 242. The reflecting cup 221 is a recess formed in a white ceramic material or a ceramic material with a good reflection characteristic. Accordingly, the light from the LED die 25 can be effectively directed in the direction of the convex lens 28.

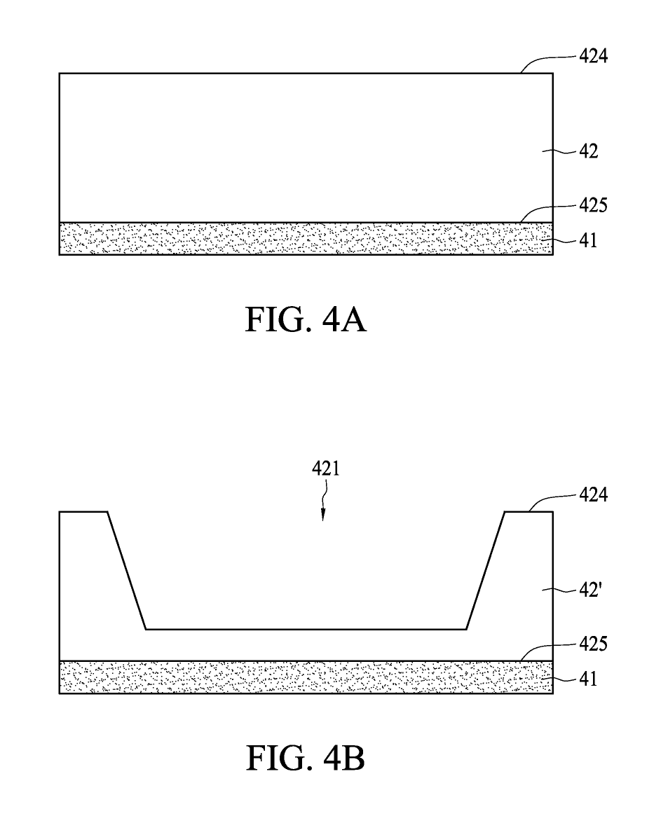

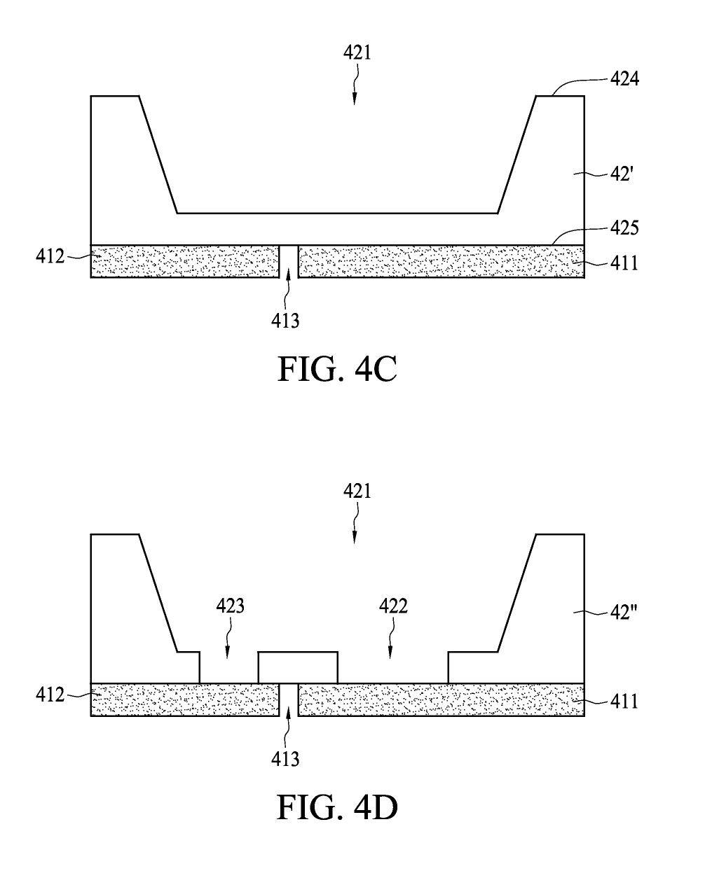

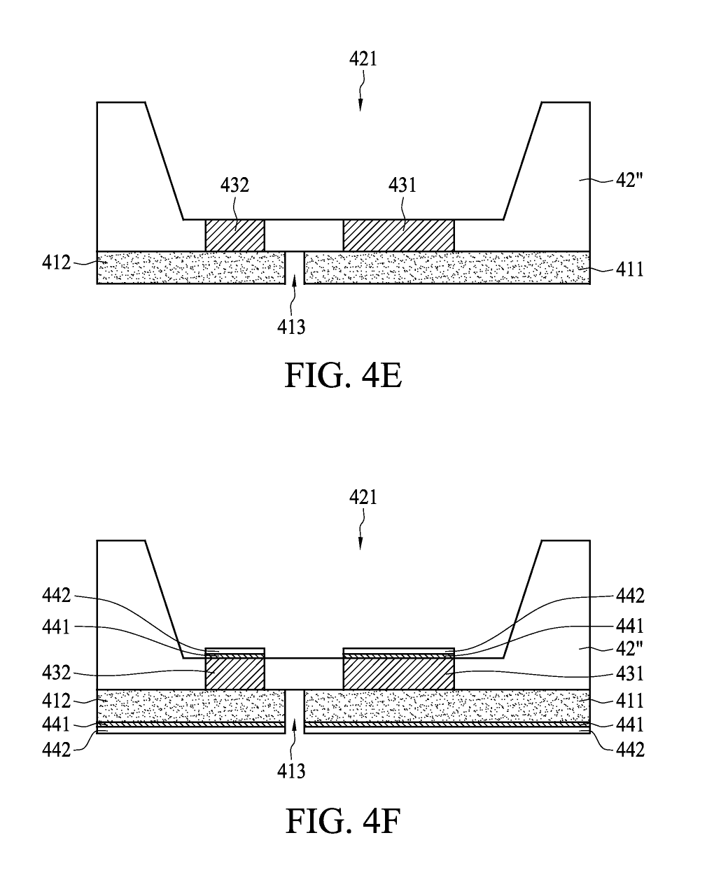

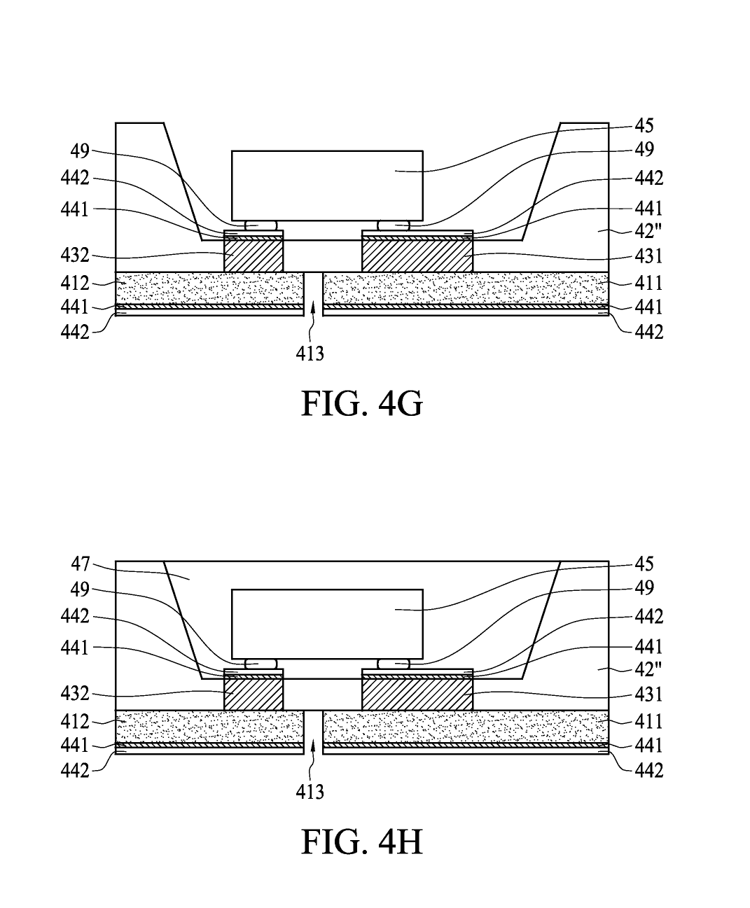

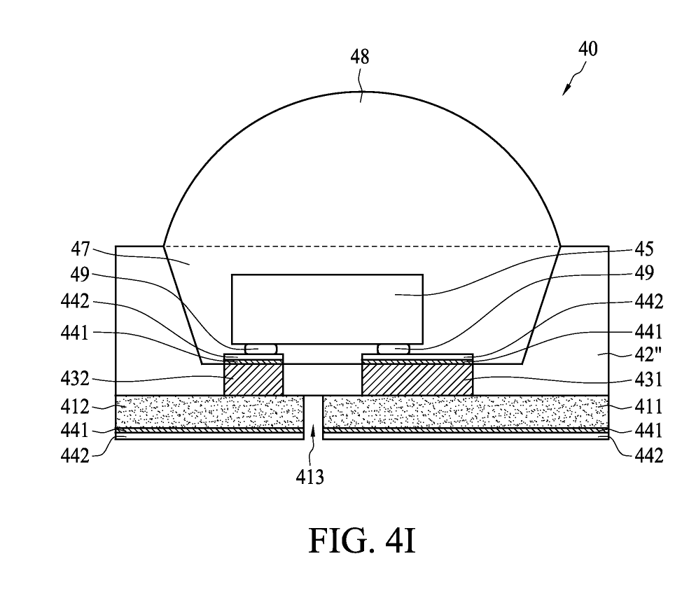

FIGS. 4A-4I are schematic diagrams illustrating the manufacturing steps of the ceramic package structure of a high power light emitting diode in accordance with another embodiment of the present invention. As shown in FIG. 4A, an electrical conductive film 41 is fixed to a second surface 425 of a ceramic substrate 42 by a thermal compression method, wherein the ceramic substrate 42 is an LTCC sheet or an HTCC sheet and the electrical conductive film 41 is a copper film.

Referring to FIG. 4B, a reflecting cup 421 is formed on the first surface 424 of the ceramic substrate 42′ using a mechanical drilling method or a laser drilling method. The reflecting cup 421 can direct all of the light from the LED die in a certain direction (for example, an upward direction is shown in this figure) for emission. Alternatively, the concave reflecting cup 421 is formed on the first surface 424 during the solidification period of the ceramic substrate 42′. No sequential steps such as drilling are needed to form the reflecting cup 421. Thereafter, photolithography, photoresist development and metal etching processes are performed to form a groove 413 on the electrical conductive film 41 for obtaining a default electrode pattern, as shown in FIG. 4C. Accordingly, the first electrode 411 and the second electrode 412 are formed on the second surface 425 of the ceramic substrate 42′.

Similarly, a plurality of through holes 422 and 423 are formed on the bottom of the reflecting cup 421 of the ceramic substrate 42″ using a mechanical drilling method or a laser drilling method, as shown in FIG. 4D. Thereafter, an electrical conductive material such as silver paste, adhesive with silver powders or metal deposited by electroforming is filled in the through holes 422 and 423 to form conductive rods 431 and 432 as a charging circuit and to increase the support stiffness of the structure, as shown in FIG. 4E.

In order to improve the solderability of the first electrode 411 and the second electrode 412 of the ceramic substrate 42″, nickel, gold, palladium, or silver as an assistant metal layer is sequentially deposited on the first electrode 411 and the second electrode 412 by electrolysis plating or chemical plating. As shown in FIG. 4F, a nickel layer 441 and a gold layer 442 are not only sequentially deposited on the first electrode 411 and the second electrode 412, but also are plated on the exposed surfaces of the electrical conductive rods 431 and 432 and are useful for the connections of sequential package processes.

An LED die 45 is attached on the conductive rods 431 and 432 further using flip-chip bonding, as shown in FIG. 4G. The circuit surface of the LED die 45 faces toward the conductive rods 431 and 432, and is connected to the conductive rods 431 and 432 through the solder bump 49. After the solder bump 49 is reflowed, the soldering material is melted and then solidified again. The conductive rods 431, 432 and the solder bump 49 are connected to each other, so a vertical current path is obtained, as shown in FIG. 4G. Compared with FIG. 2H, the advantage of this embodiment includes a shorter current path and better thermal dissipation. Furthermore, the loop height of the metal wire for wire bonding can also be reduced.

As shown in FIG. 4H, in order to protect the LED die 45 from the effects of environmental factors and external force, transparent adhesive 47 such as epoxy and silicone gel can be filled into the reflecting cup 421. The transparent adhesive 47 is filled into the reflecting cup 421 using transfer molding or injection molding to cover the entire LED die 45 for waterproofing and protection. Scattering dots such as titania (TiO₂) or silica (SiO₂) can be added to the transparent adhesive 47.

In order to improve the focusing effect of the LED ceramic package structure 40, a convex lens 48 can be mounted to the upper surface of the transparent adhesive 47, as shown in FIG. 4I. The convex lens 48 is formed by injection molding in advance, and is attached to the upper surface of the transparent adhesive 47. Alternatively, the transparent adhesive 47 and the convex lens 48 are integrated into one part by a single step of transfer molding or injection molding, so the manufacturing steps are reduced and the interface capable of reflecting light is eliminated.

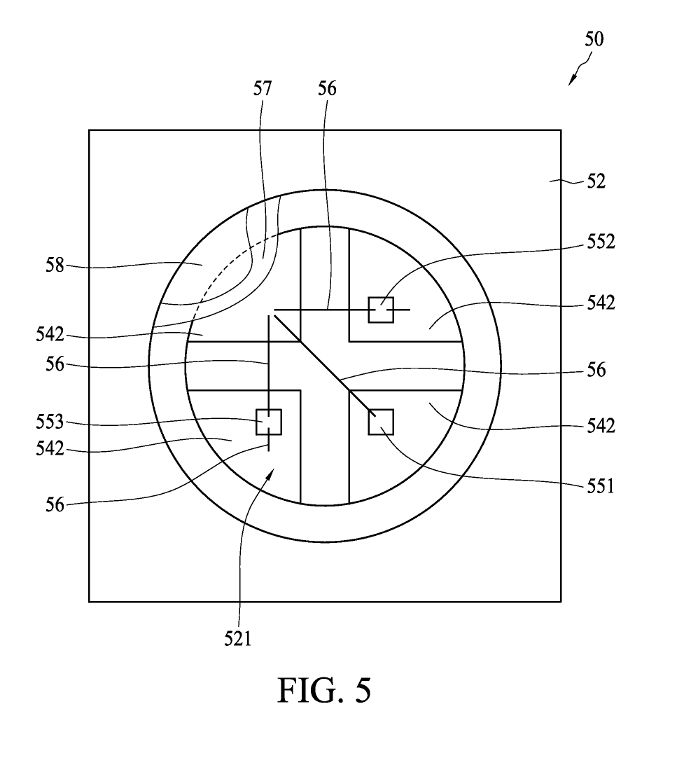

FIG. 5 is a top view of the ceramic package structure of a high power light emitting diode in accordance with another embodiment of the present invention. The LED ceramic package structure 50 comprises three LED dies 551-553 respectively emitting red, green and blue lights such that white light is obtained by combining them. The three lights are combined in the transparent adhesive 57, and the combined light is emitted from the package structure 50 via the convex lens 58 on the transparent adhesive 57.

Four areas of a gold layer 542 are overlaid on the bottom of the reflecting cup 521 of the ceramic substrate 52. The four areas are on four conductive rods (not shown in FIG. 5), and the LED dies 551-553 are respectively mounted on the corresponding areas of the gold layer 542. The red LED die 551 is electrically connected through a metal wire 56 to the area of the gold layer 542 on which no die is mounted. The green and blue LED dies 552-553 are respectively connected through a metal wire 56 to the area of the gold layer 542 on which no die is mounted. Generally, the substrates of the red and blue LED dies 552-553 are electrically nonconductive. Therefore, two additional metal wires 56 are needed to respectively and electrically connect the two dies to the areas of the gold layer 542 on which they are mounted. The reflecting cup 521 is a recess formed in a white ceramic material or a ceramic material with a good reflection characteristic. Accordingly, the light from the LED dies 551-553 can be effectively directed in the direction of the convex lens 58.

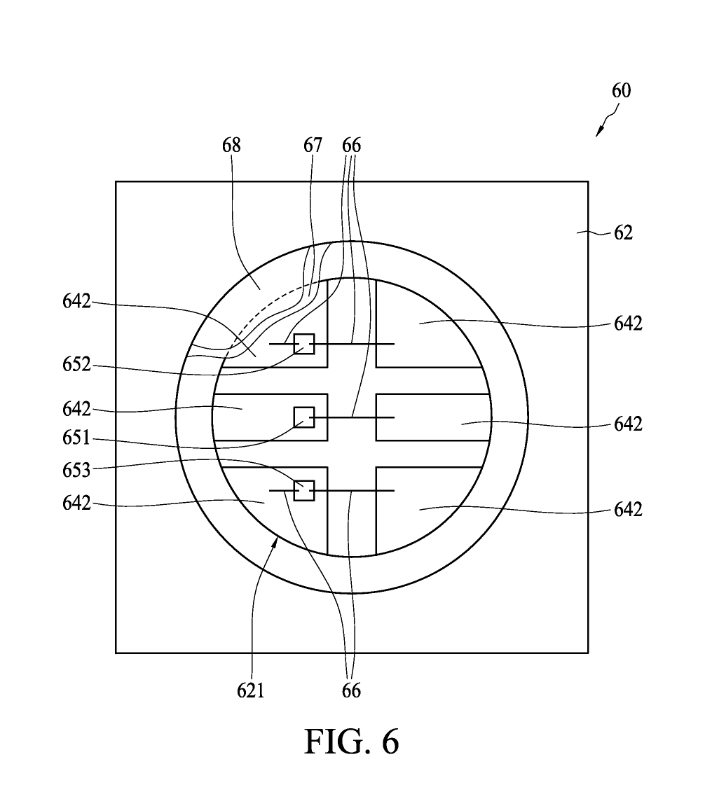

FIG. 6 is a top view of the ceramic package structure of a high power light emitting diode in accordance with another embodiment of the present invention. The LED ceramic package structure 60 comprises three LED dies 651-653 respectively emitting red, green and blue lights such that white light is obtained by combining them. The three lights are combined in the transparent adhesive 67, and the combined light is emitted from the package structure 60 via the convex lens 68 on the transparent adhesive 67.

In contrast to the embodiment shown in FIG. 5, there are six areas of the gold layer 642 on the bottom of the reflecting cup 621 of the ceramic substrate 62 according to the embodiment of FIG. 6. The six areas are on six conductive rods (not shown in FIG. 6), and the LED dies 651-653 are respectively mounted on the corresponding areas of the gold layer 642. The red LED die 651 is electrically connected through a metal wire 66 to the corresponding area of the gold layer 642 on which no die is mounted. The green and blue LED dies 652-653 are respectively connected through the metal wire 66 to the corresponding areas of the gold layer 642 on which no die is mounted. Generally, the substrates of the red and blue LED dies 652-653 are electrically nonconductive. Therefore, two additional metal wires 66 are needed to respectively and electrically connect the two dies to the areas of the gold layer 642 on which they are mounted. The LED dies 651-653 can be independently controlled by current supply. In this regard, the circuit design is different from the embodiment of FIG. 5 that shares a common anode.

The reflecting cup 621 is a recess formed in a white ceramic material or a ceramic material with a good reflection characteristic. Accordingly, the light from the LED dies 651-653 can be effectively directed in the direction of the convex lens 68.

The above-described embodiments of the present invention are intended to be illustrative only. Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A ceramic package structure of a high power light emitting diode, comprising:
a ceramic substrate including a first surface, a second surface opposite the first surface, a reflecting cup disposed on the first surface, and at least two through holes disposed on the bottom of the reflecting cup;
an electrical conductive film including a first electrode and a second electrode, and fixed on the second surface;
at least two conductive rods respectively filled in the at least two through holes, and respectively connected to the first electrode and the second electrode; and
a light emitting diode die mounted on one or two of the conductive rods, and electrically connected to the at least two conductive rods.

2. The ceramic package structure of a high power light emitting diode according to claim 1, further comprising transparent adhesive filled into the reflecting cup, wherein the material of the transparent adhesive is epoxy or silicone gel.

3. The ceramic package structure of a high power light emitting diode according to claim 2, further comprising a convex lens disposed on the transparent adhesive.

4. The ceramic package structure of a high power light emitting diode according to claim 2, further comprising a plurality of scattering dots mixed with the transparent adhesive, wherein the material of the scattering dots is titania (TiO₂) or silica (SiO₂).

5. The ceramic package structure of a high power light emitting diode according to claim 1, further comprising at least an assistant metal layer formed on the first electrode, the second electrode, and the at least two conductive rods, wherein the assistant metal layer is a solderable metal.

6. The ceramic package structure of a high power light emitting diode according to claim 1, wherein the light emitting diode die is mounted on one of the conductive rods by wire-bonding or flip-chip bonding.

7. A method for manufacturing a ceramic package structure of a high power light emitting diode, comprising the steps of:
compressing an electrical conductive film to attach to a surface of a ceramic substrate, wherein another surface of the ceramic substrate opposite the electrical conductive film comprises a reflecting cup with at least one concave;
patterning the electrical conductive film to form at least one first electrode and at least one second electrode;
forming at least two through holes on the bottom of the reflecting cup;
respectively filling at least two conductive rods in the at least two through holes, wherein the at least two conductive rods are respectively connected to the first electrode and the second electrode;
mounting an LED die on one or two of the conductive rods; and
electrically connecting the LED die to the at least two conductive rods.

8. The method for manufacturing a ceramic package structure of a high power light emitting diode according to claim 7, further comprising a step of filling transparent adhesive into the reflecting cup, wherein the transparent adhesive is filled into the reflecting cup using transfer molding or injection molding.

9. The method for manufacturing a ceramic package structure of a high power light emitting diode according to claim 8, further comprising a step of forming or fixing a convex lens on the transparent adhesive.

10. The method for manufacturing a ceramic package structure of a high power light emitting diode according to claim 7, further comprising a step of forming at least an assistant metal layer on the first electrode, the second electrode, and the at least two conductive rods, wherein the assistant metal layer is formed by electrolysis plating or chemical plating.

11. The method for manufacturing a ceramic package structure of a high power light emitting diode according to claim 7, wherein the reflecting cup is a recess formed during a solidification period of the ceramic substrate.

12. The method for manufacturing a ceramic package structure of a high power light emitting diode according to claim 7, wherein the LED die is mounted on one of the conductive rods by die bonding or flip-chip bonding.

13. The method for manufacturing a ceramic package structure of a high power light emitting diode according to claim 7, wherein the first electrode and the second electrode of the electrical conductive film are formed by photolithography, photoresist development and metal etching processes.

14. A ceramic package structure of a high power light emitting diode, comprising:
a ceramic substrate including a first surface, a second surface opposite the first surface, a reflecting cup disposed on the first surface, and at least two through holes disposed on the bottom of the reflecting cup;
an electrical conductive film including a plurality of first electrodes and a plurality of second electrodes, and fixed on the second surface;
a plurality of conductive rods respectively filled in the at least two through holes, and respectively connected to the first electrode and the second electrode; and
a plurality of light emitting diode dies respectively mounted on at least one of the conductive rods, and electrically connected to at least two of the conductive rods.

15. The ceramic package structure of a high power light emitting diode according to claim 14, wherein the plurality of light emitting diode dies comprises red, green, and blue light emitting diode dies.

16. The ceramic package structure of a high power light emitting diode according to claim 14, further comprising transparent adhesive filled into the reflecting cup, wherein the material of the transparent adhesive is epoxy or silicone gel.

17. The ceramic package structure of a high power light emitting diode according to claim 16, further comprising a convex lens disposed on the transparent adhesive.

18. The ceramic package structure of a high power light emitting diode according to claim 16, further comprising a plurality of scattering dots mixed with the transparent adhesive, wherein the material of the scattering dots is titania (TiO₂) or silica (SiO₂).

19. The ceramic package structure of a high power light emitting diode according to claim 14, further comprising at least an assistant metal layer formed on the first electrodes, the second electrodes, and the conductive rods, wherein the assistant metal layer is a solderable metal and the solderable metal is nickel, gold, palladium, or silver.

20. The ceramic package structure of a high power light emitting diode according to claim 14, further comprising a plurality of metal wires connected to the light emitting diode dies and the conductive rods or a plurality of bumps connected to the light emitting diode dies and the conductive rods.
